(19) United States
(12) Patent Application Publication
(10) Pub. No.: US 2025/0260343 A1
(43) Pub. Date: Aug. 14, 2025

(54) ENERGY EXTRACTION ARRANGEMENT, METHOD, AND SYSTEM

(71) Applicant: Baker Hughes Oilfield Operations LLC, Houston, TX (US)

(72) Inventors: Andrew Duggan, Meadows Place, TX (US); Daniel C. Ewing, Katy, TX (US); Christopher Hern, Porter, TX (US); Ronnie Russell, Cypress, TX (US); Kamalesh Chatterjee, Tomball, TX (US)

(21) Appl. No.: 18/437,838

(22) Filed: Feb. 9, 2024

(51) Int. Cl. H02N 2/18; E21B 41/00; H10N 30/30; H10N 30/88

(52) U.S. Cl. CPC H02N 2/185; E21B 41/0085; H10N 30/30; H10N 30/88

(57) ABSTRACT

An energy extraction arrangement, includes a surface defining a flow pathway, and a flap hingedly secured to the surface, the flap exposed to a fluid flow, during use. A borehole energy extraction system, including a non-diverted primary flow pathway for borehole fluids, a surface defining the flow pathway, and a flap hingedly secured to the surface, the flap exposed to a fluid flow, during use. A method for extracting energy from a non-diverted primary fluid flow, the method including deflecting solely by the primary fluid flow a flap hingedly connected to a surface defining in part a flow pathway for the primary fluid flow, and generating an electrical potential by the deflecting. A borehole system, including a borehole in a subsurface formation, a string in the borehole, and an energy extraction arrangement disposed within or as a part of the string.

### BACKGROUND

In the resource recovery and fluid sequestration industries power in the downhole environment is both essential and scarce. Power from surface can satisfy needs but requires conductors that take valuable space in the borehole. Batteries provide sufficient power but for a critically limited amount of time relative to the lifetime of a wellbore. The art would be benefitted by arrangements that could provide power to downhole systems without the drawbacks noted above.

### SUMMARY

An embodiment of an energy extraction arrangement, including a surface at least in part defining a flow pathway, and a flap hingedly secured to the surface, the flap exposed to a fluid flow along the surface, during use.

An embodiment of a borehole energy extraction system, including a non-diverted primary flow pathway for borehole fluids, a surface at least in part defining the flow pathway, and a flap hingedly secured to the surface, the flap exposed to a fluid flow along the primary flow pathway, during use.

An embodiment of a method for extracting energy from a non-diverted primary fluid flow, the method including deflecting solely by the primary fluid flow a flap hingedly connected to a surface defining in part a flow pathway for the primary fluid flow, and generating an electrical potential by the deflecting.

An embodiment of a borehole system, including a borehole in a subsurface formation, a string in the borehole, and an energy extraction arrangement disposed within or as a part of the string.

### BRIEF DESCRIPTION OF THE DRAWINGS

The following descriptions should not be considered limiting in any way. With reference to the accompanying drawings, like elements are numbered alike:

FIG. 1 is a perspective view of a tubular defining a flow path and having an energy extraction arrangement disposed therein;

FIG. 2 is an enlarged view of a portion of FIG. 1 illustrating one of the flaps in a state of being deflected by flow;

FIG. 3 is another enlarged view illustrating one possible flap and hinge configuration;

FIG. 4 is a perspective view similar to FIG. 1 but with overlapping flaps;

FIG. 5 is another perspective view similar to FIG. 4 but where the flaps have integral hinges;

FIG. 6 is a perspective view of an alternate flap geometry;

FIG. 7 is perspective view of another alternate flap geometry;

FIG. 8 is another perspective view of the FIG. 9 flap;

FIG. 9 is a perspective view similar to FIG. 1 except that the flaps are distinctly arranged;

FIG. 10 is an enlarged view of one of the flaps in FIG. 6; and

FIG. 11 is a view of a borehole system including an energy extraction arrangement as disclosed herein.

### DETAILED DESCRIPTION

A detailed description of one or more embodiments of the disclosed apparatus and method are presented herein by way of exemplification and not limitation with reference to the Figures.

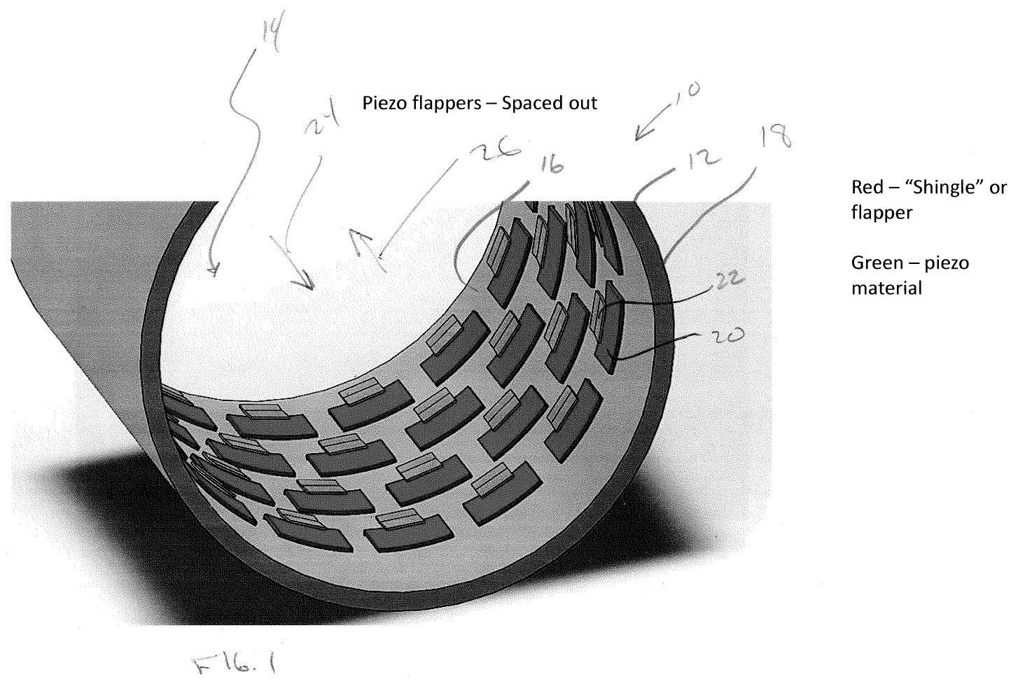

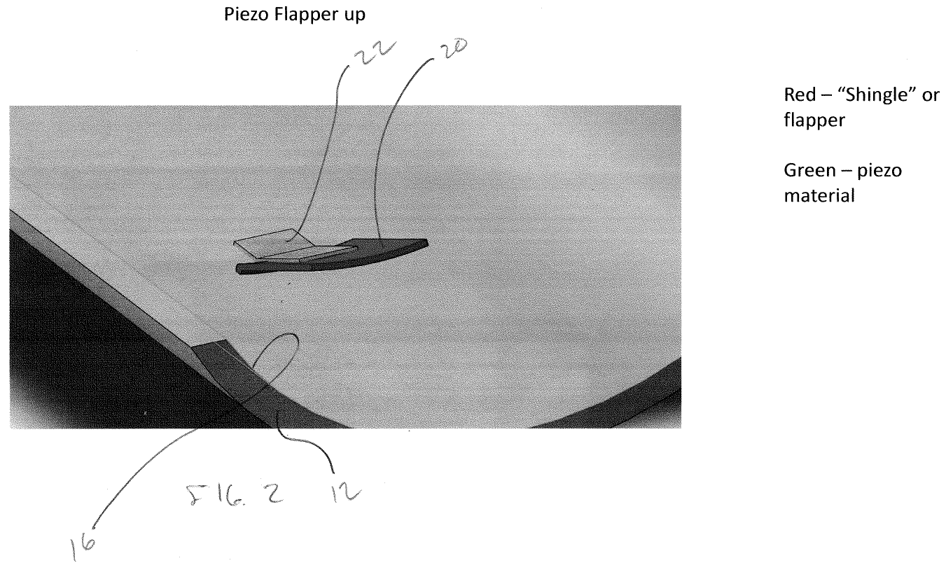

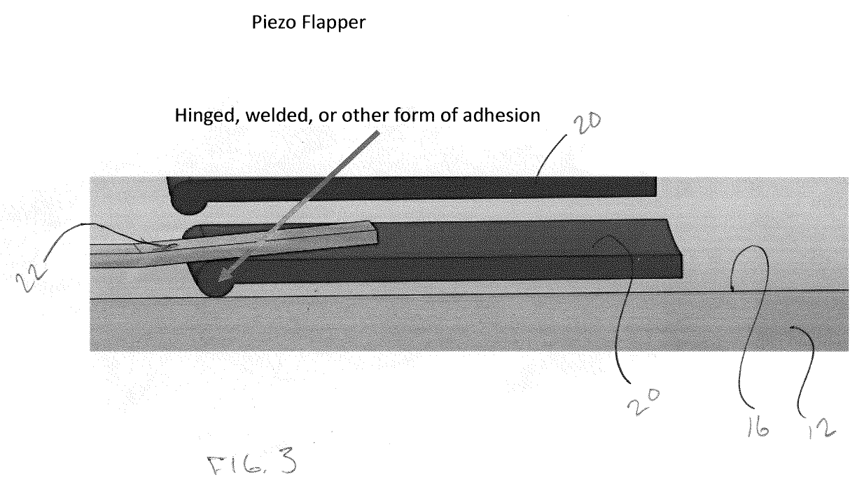

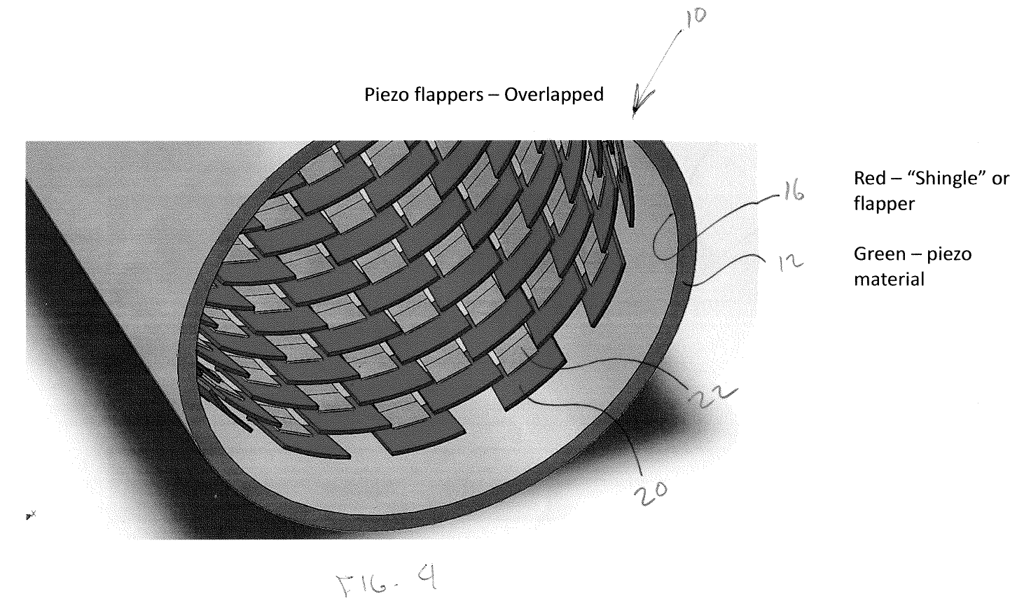

Referring to FIG. 1, an energy extraction arrangement 10 is illustrated in a tubular 12. It is to be understood that the arrangement 10 applies not only to a flow pathway 14 within the inside diameter surface 16 of a tubular 12 but could be disposed upon any surface that makes up a portion of a flow pathway, such as an outside diameter surface 18 of the tubular 12 in an annular flow space, or any other portion of a flow path regardless of how convoluted or unusually shaped the pathway 14 might be. As illustrated, the arrangement 10 includes the surface 16, which at least in part defines the flow pathway 14. As illustrated, the surface 16 defines the whole of the pathway 14 but it is contemplated that other structures might also be present or tortuosity might be present that would make the pathway 14 defined only partially by the surface 16 while still remaining a primary flow pathway through a structure, such as a tubular 12. Arrangement 10 further includes a flap 20 hingedly (or otherwise configured to allow the flap 20 to articulate relative to its securement or relative to the tubular 12) secured to the surface 16, the flap 20 being exposed to a fluid flowing along the surface 16, during use. The arrangement 10 includes a hinge 22 that supports the “hingedly secured” language above and that hinge 22 may be of a separate material secured to the flap 20 or may be a part of the flap 20 (contrast FIGS. 4 and 5 for a separate hinge 22 and an integral hinge 22, respectively). The hinge 22 may be an articulated hinge (with a through pin like a door hinge or a snap together hinge that has bumps on one side that are received in recesses on the other side, etc.), living hinge (such as one that bends, etc.), and similar configurations that allow for one portion of a device to articulate relative to another portion of the device to which the first part is attached via the hinge. that provides for the movement of the flap under the influence of flowing fluid therepast and where at least some portion of the flap 20/hinge 22 will deflect (physically deform). The hinge 22 or the flap 20 or both may comprise a piezo electric material so that upon deflection thereof, with flap 20 movement, a potential is generated in the material. An electrical potential in such a material may be collected in a traditional way (used for piezoelectric devices in other industries for different purposes) and used to power electronics or charge a battery, for example. Referring to FIG. 2, an enlarged view illustrates one flap 20 with its hinge 22 deflected because the flap 20 has been pulled toward the flowing fluid. FIG. 3 provides a more enlarged view of the flap 20 and hinge 22.

FIGS. 1, 4, and 5 illustrate different patterns of the flaps 20 with FIG. 1 illustrates flaps 20 being spaced apart while FIGS. 4 and 5 illustrate flaps 20 being overlapped. It is to be appreciated that the overlapped FIG. 5 illustration of the hinge 22 as integral with the flap 20 is also contemplated for FIG. 1. Specifically, FIG. 1 could be replicated with integral hinges as are shown in FIG. 5.

Depending upon flow direction through the illustrated embodiments of FIGS. 1, 4, and 5, different physical effects are brought to bear to deflect the flap 20 and/or the hinge 22 for generation of a potential. If the flow in FIG. 1 is in the direction of arrow 24, then flap 20 is lifted by a reduction of pressure of the fluid flowing in the pathway 14, such as in accordance with the Bernoulli principle. In the event the flow is in the opposite direction, as in arrow 26, then flap 20 and/or hinge 22 are lifted by catching flow and being pushed up by the flow. The same is true for FIGS. 4 and 5. Regardless of lift mechanism, the action of lifting the flap 20 and/or the hinge 22 results in physical deformation of the piezo electric material of one, the other, or both of the flap 20 and the hinge 22 to produce a potential. Changes in the flow regime, including turbulent flow in boundary layers over time will cause a repositioning of the flap 20 and/or the hinge 22. Repositioning changes the physical stress in the piezoelectric material to again produce a potential that can be harvested. In embodiments, the geometries of the flaps and the flow regime work in concert to cause the flaps 20 to flutter, which causes cyclic stress in the piezoelectric material and hence continuous potential generation.

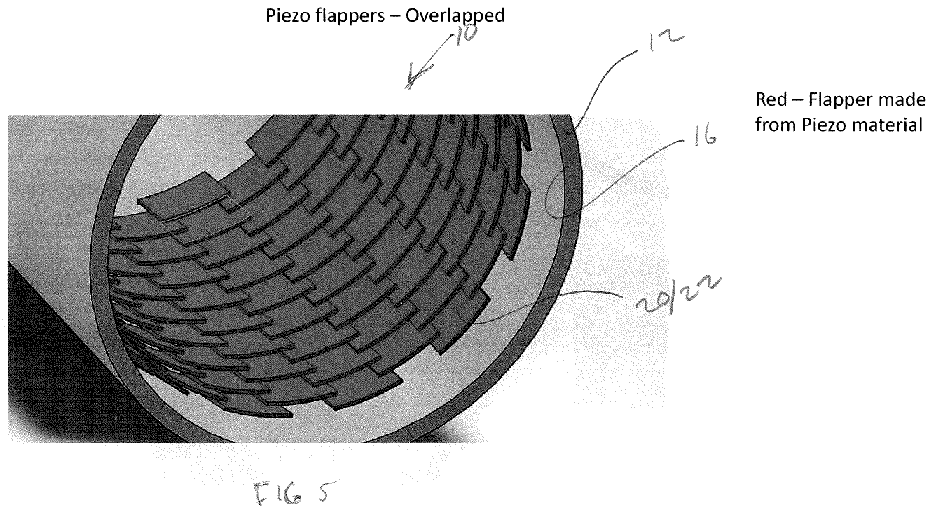

While the geometries of the flaps illustrated in the forgoing figures are fully functional for the purposes disclosed, additional geometries are also contemplated. These are illustrated in FIGS. 6-8.

Referring to FIG. 6, it will be appreciated that the flap 20 is illustrated in a W or gable shape cross section. It is to be understood that the number of bends in the flap is not limited to the 3 that create a W shape but could also be more or fewer. The geometry of FIG. 6 is configured to increase the fluid access underneath the flap 20 (arrow 21) to encourage lifting of the flap 20 during fluid flow thereacross.

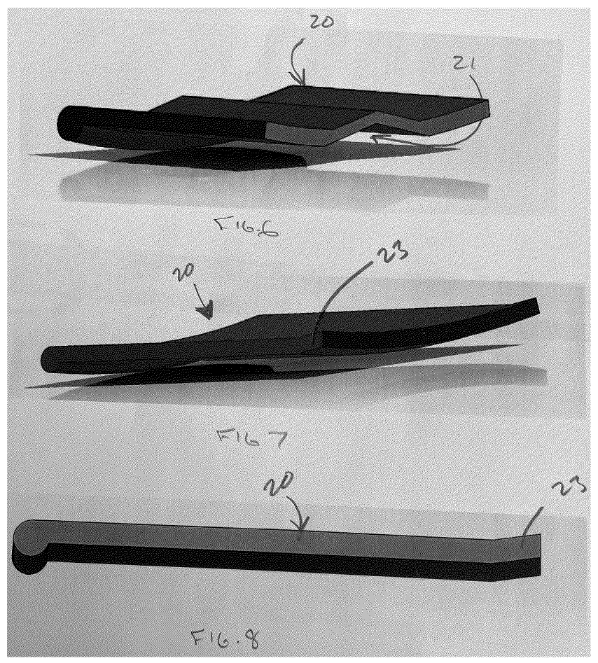

Referring to FIGS. 7 and 8, another geometry of flap 20 is illustrated and has the same intent as FIG. 6, namely to encourage fluid access below the flap 20 (between the flap 20 and surface 16. This embodiment accomplishes this result through the use of a lip 23. Since the lip 23 bends up further into the flow pathway 14, an underside 25 of the flap 20 is more easily accessed by fluid, which tends to lift the flap 20.

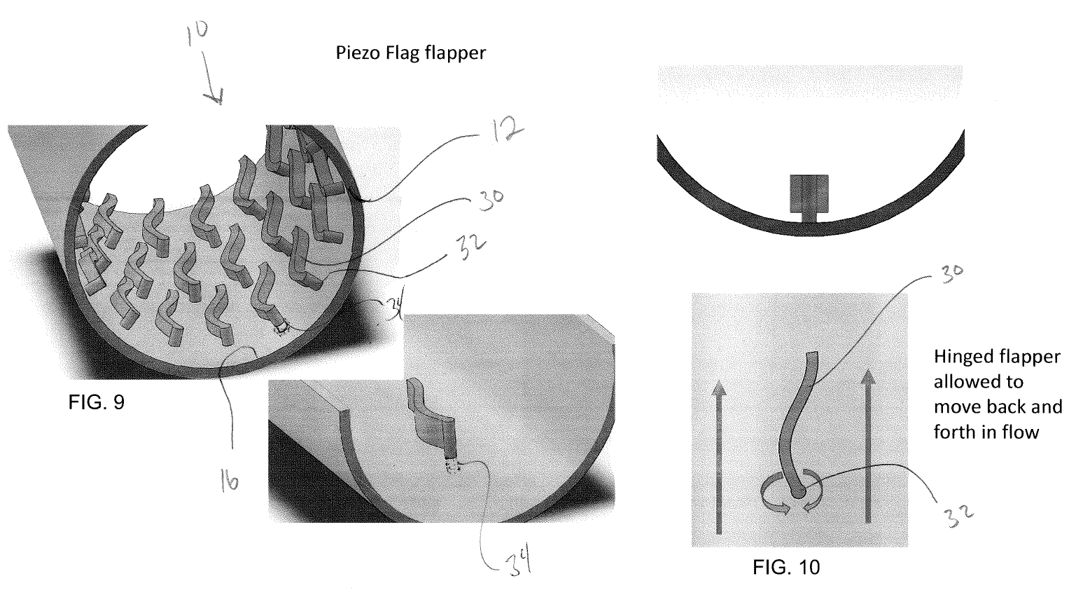

Referring to FIGS. 9 and 10, another embodiment is illustrated. In this embodiment a flap 30 is employed which is secured to surface 16 in a way that allows the flap 30 to essentially flap in the breeze of fluid flowing therepast. The flapping would be similar to what a flag does in a breeze. This flapping will cause bending in the flap 30 or in a hinge 32 or both to produce a potential similar to the foregoing embodiments. In an embodiment, the hinge 32 includes a pin that is received in a recess 34 of the tubular 12, such as a drill hole therein.

In each embodiment disclosed, there is very little impact on the flow regime of the system. Flow is not diverted out of a primary flow into a secondary flow path and nothing significantly interrupts the primary flow path. Rather, the flaps 20 or and hinges 22 or 32 sit against the surface 16 and generate potential without significant flow alteration (e.g., less than about 5% of energy in the flow affected).

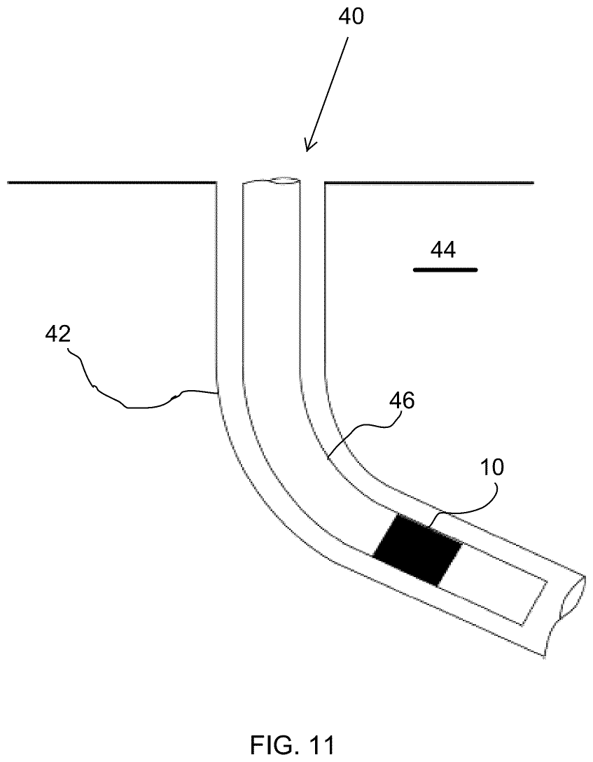

Referring to FIG. 11, a borehole system 40 is illustrated. The system 40 comprises a borehole 42 in a subsurface formation 44. A string 46 is disposed within the borehole 40. An energy harvester 10 as disclosed herein is disposed within or as a part of the string 46.

Set forth below are some embodiments of the foregoing disclosure:

Embodiment 1: An energy extraction arrangement, including a surface at least in part defining a flow pathway, and a flap hingedly secured to the surface, the flap exposed to a fluid flow along the surface, during use.

Embodiment 2: The arrangement as in any prior embodiment, wherein during use, the flap and/or the hinge is deflected due to changes in the flowing fluid.

Embodiment 3: The arrangement as in any prior embodiment, wherein the flap comprises a piezoelectric material.

Embodiment 4: The arrangement as in any prior embodiment, wherein the hinge is separate from the flap and secured to the flap to provide the hinged connection to the surface.

Embodiment 5: The arrangement as in any prior embodiment, wherein the hinge comprises a piezoelectric material.

Embodiment 6: The arrangement as in any prior embodiment, wherein the flap includes a lip geometry configured to cause lift and or drag, during use.

Embodiment 7: The arrangement as in any prior embodiment, wherein the flap comprises an airfoil.

Embodiment 8: The arrangement as in any prior embodiment, wherein the flap comprises a W or gable shaped cross sectional geometry.

Embodiment 9: The arrangement as in any prior embodiment, wherein the flap is a plurality of flaps.

Embodiment 10: The arrangement as in any prior embodiment, wherein ones of the plurality of flaps overlap other ones of the plurality of flaps.

Embodiment 11: The arrangement as in any prior embodiment, wherein the flap extends from the hinge in a downstream direction.

Embodiment 12: The arrangement as in any prior embodiment, wherein the flap extends from the hinge in an upstream direction.

Embodiment 13: The arrangement as in any prior embodiment, wherein the flap when at rest lays substantially flat against the surface.

Embodiment 14: The arrangement as in any prior embodiment, wherein the flap when at rest is substantially normal to the surface.

Embodiment 15: A borehole energy extraction system, including a non-diverted primary flow pathway for borehole fluids, a surface at least in part defining the flow pathway, and a flap hingedly secured to the surface, the flap exposed to a fluid flow along the primary flow pathway, during use.

Embodiment 16: The system as in any prior embodiment, wherein energy in the primary flow is reduced by less than about 5%.

Embodiment 17: A method for extracting energy from a non-diverted primary fluid flow, the method including deflecting solely by the primary fluid flow a flap hingedly connected to a surface defining in part a flow pathway for the primary fluid flow, and generating an electrical potential by the deflecting.

Embodiment 18: The method as in any prior embodiment, wherein the deflecting is at the hinge.

Embodiment 19: The method as in any prior embodiment, wherein the deflecting is based upon fluid flowing in a direction that encounters the hinge first and a remainder of the flap second.

Embodiment 20: The method as in any prior embodiment, wherein the deflecting is based upon fluid flowing in a direction that encounters the hinge second and a remainder of the flap first.

Embodiment 21: A borehole system, including a borehole in a subsurface formation, a string in the borehole, and an energy extraction arrangement as in any prior embodiment, disposed within or as a part of the string.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% of a given value.

The teachings of the present disclosure may be used in a variety of well operations. These operations may involve using one or more treatment agents to treat a formation, the fluids resident in a formation, a borehole, and/or equipment in the borehole, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. An energy extraction arrangement, comprising:
a surface at least in part defining a flow pathway; and
a flap hingedly secured to the surface, the flap exposed to a fluid flow along the surface, during use.

2. The arrangement as claimed in claim 1, wherein during use, the flap and/or the hinge is deflected due to changes in the flowing fluid.

3. The arrangement as claimed in claim 1, wherein the flap comprises a piezoelectric material.

4. The arrangement as claimed in claim 1, wherein the hinge is separate from the flap and secured to the flap to provide the hinged connection to the surface.

5. The arrangement as claimed in claim 4, wherein the hinge comprises a piezoelectric material.

6. The arrangement as claimed in claim 1, wherein the flap includes a lip geometry configured to cause lift and or drag, during use.

7. The arrangement as claimed in claim 1, wherein the flap comprises an airfoil.

8. The arrangement as claimed in claim 1, wherein the flap comprises a W or gable shaped cross sectional geometry.

9. The arrangement as claimed in claim 1, wherein the flap is a plurality of flaps.

10. The arrangement as claimed in claim 8, wherein ones of the plurality of flaps overlap other ones of the plurality of flaps.

11. The arrangement as claimed in claim 1, wherein the flap extends from the hinge in a downstream direction.

12. The arrangement as claimed in claim 1, wherein the flap extends from the hinge in an upstream direction.

13. The arrangement as claimed in claim 1, wherein the flap when at rest lays substantially flat against the surface.

14. The arrangement as claimed in claim 1, wherein the flap when at rest is substantially normal to the surface.

15. A borehole energy extraction system, comprising:
a non-diverted primary flow pathway for borehole fluids;
a surface at least in part defining the flow pathway; and
a flap hingedly secured to the surface, the flap exposed to a fluid flow along the primary flow pathway, during use.

16. The system as claimed in claim 15, wherein energy in the primary flow is reduced by less than about 5%.

17. A method for extracting energy from a non-diverted primary fluid flow, the method comprising:
deflecting solely by the primary fluid flow a flap hingedly connected to a surface defining in part a flow pathway for the primary fluid flow; and
generating an electrical potential by the deflecting.

18. The method as claimed in claim 17, wherein the deflecting is at the hinge.

19. The method as claimed in claim 17, wherein the deflecting is based upon fluid flowing in a direction that encounters the hinge first and a remainder of the flap second.

20. The method as claimed in claim 17, wherein the deflecting is based upon fluid flowing in a direction that encounters the hinge second and a remainder of the flap first.

21. A borehole system, comprising:
a borehole in a subsurface formation;
a string in the borehole; and
an energy extraction arrangement as claimed in claim 1, disposed within or as a part of the string.
